(19) United States
(12) Patent Application Publication
(10) Pub. No.: US 2011/0079708 A1
(43) Pub. Date: Apr. 7, 2011

(54) SILICON PHOTODETECTION MODULE

(76) Inventors: Yue-Ming Hsin, Tainan City (TW); Fang-Ping Chou, Yonghe City (TW); Guan-Yu Chen, Taichung City (TW)

(21) Appl. No.: 12/754,098

(22) Filed: Apr. 5, 2010

(30) Foreign Application Priority Data
Oct. 6, 2009 (TW) 098133807

(51) Int. Cl. H01L 31/102; H03F 3/08

(52) U.S. Cl. 250/214 A

(57) ABSTRACT

A silicon photo-detection module is disclosed, in which a silicon photodiode detection unit and a parasitical vertical bipolar junction transistor amplification unit can be simultaneously formed by a CMOS process. The silicon photo-detection module has a silicon substrate, a silicon photodiode detection unit comprising a positive portion and a negative portion, and a parasitical vertical bipolar junction transistor amplification unit comprising a collector, a base, and an emitter. The silicon photodiode detection unit and the parasitical vertical bipolar junction transistor amplification unit are formed on the silicon substrate by a CMOS process. Besides, the positive and negative portions of the silicon photodiode detection unit are electrically connected respectively with the base and the collector of the parasitical vertical bipolar junction transistor amplification unit.

### BACKGROUND OF THE INVENTION

1. Field of the Invention

The present invention relates to a silicon photodetection module and, more particularly, to a silicon photodetection module in which a silicon photodiode detection unit and a parasitical vertical bipolar junction transistor amplification unit can be simultaneously formed by a CMOS process.

2. Description of Related Art

In a technical field of short wavelength optical communication, a silicon photodetector is commonly used as a photodetection device. However, because the photocurrent photoelectrically converted from the silicon photodetector is very slight, such photocurrent cannot be applied directly, and needs to be improved. Therefore, several solutions of the abovementioned problems have been reported. One of these solutions is to arrange a plurality of silicon photodetectors in an array so as to form a silicon photodetector array as shown in FIG. 1. The silicon photodetector array is made by the following procedures. First, using a CMOS process, a plurality of negative wells 11 and positive wells 12 are arranged on a positive silicon substrate 13. Second, the adjacent negative wells 11 and positive wells 12 are constituted into a silicon photodetector 14 so as to form multiple silicon photodetectors 14, i.e. to form a silicon photodetector array on the positive silicon substrate 13. In addition, in order to increase the induced photocurrent, these silicon photodetectors 14 must be electrically connected in parallel. However, this results in that the corresponding wiring pattern of these silicon photodetectors 14 becomes very complex. Furthermore, these silicon photodetectors 14 cover a specific portion of the surface area of the positive silicon substrate 13, and this results in increasing difficulty in scaling down the photodetection device having the silicon photodetector array as shown in FIG. 1.

For this reason, a bipolar junction phototransistor unit has been conceived in which a base-collector junction diode serves as a photodetection region. Nevertheless, integration of such bipolar junction phototransistor unit and a silicon photodiode detection unit into a bipolar junction phototransistor has to be accomplished by a complex bipolar complementary metal oxide semiconductor (BiCMOS) process, leading to significant difficulty in reduction of the manufacturing cost.

Hence, it is desirable to manufacture a silicon photodetection module by a CMOS process, and the silicon photodetection module has a parasitical vertical bipolar junction transistor amplification unit which can directly amplify photocurrent.

### SUMMARY OF THE INVENTION

An object of the present invention is to provide a silicon photodetection module in which a silicon photodiode detection unit and a parasitical vertical bipolar junction transistor amplification unit can be simultaneously formed by a CMOS process.

Another object of the present invention is to provide a silicon photodetection module, which can be made by a low-cost, non-complex process, and has a silicon photodiode detection unit and a parasitical vertical bipolar junction transistor amplification unit simultaneously made.

To achieve the objects mentioned above, the silicon photodetection module for light detection of the present invention comprises: a silicon substrate; a silicon photodiode detection unit, comprising a positive portion and a negative portion; and a parasitical vertical bipolar junction transistor amplification unit, comprising a collector, a base, and an emitter. The silicon photodiode detection unit and the parasitical vertical bipolar junction transistor amplification unit are formed on the silicon substrate by a complementary metal oxide semiconductor (CMOS) process. Besides, the positive portion of the silicon photodiode detection unit is electrically connected with the base of the parasitical vertical bipolar junction transistor amplification unit by a first conductive part, and the negative portion of the silicon photodiode detection unit is electrically connected with the collector of the parasitical vertical bipolar junction transistor amplification unit by a second conductive part.

Therefore, since the parasitical vertical bipolar junction transistor amplification unit comprised in the silicon photodetection module of the present invention is formed on the silicon substrate by a CMOS process, the CMOS process can simultaneously form the silicon photodiode detection unit and the parasitical vertical bipolar junction transistor amplification unit comprised in the silicon photodetection module of the present invention. Accordingly, the formation of the silicon photodiode detection unit and the parasitical vertical bipolar junction transistor amplification unit can simultaneously be accomplished in the silicon photodetection module of the present invention. Compared with a conventional bipolar phototransistor made by a bipolar complementary metal oxide semiconductor (BiCMOS) process, the silicon photodetection module of the present invention can be made by a relatively simple process and incur low cost. In addition, because there is no need to assemble a plurality of the silicon photodiode detection units into an array, the surface area of the silicon substrate occupied by the silicon photodetection module of the present invention is considerably confined in a small portion, and thus it is advantageous to scale down volume of a photodetector having the silicon photodetection module of the present invention. In the present invention, the type of silicon substrate is not limited, and it can be a positive or negative silicon substrate. In the present invention, the kind of the first conductive part is not limited, and it can be any kind of metal wire but preferably is a gold wire. In the present invention, the kind of the second conductive part is not limited, and it can be any kind of metal wire but preferably is a gold wire. In the present invention, the wavelength of the light detected by the silicon photodetection module is not limited. For example, the wavelength can range from 350 nm to 1,000 nm.

Other objects, advantages, and novel features of the invention will become more apparent from the following detailed description when taken in conjunction with the accompanying drawings.

### BRIEF DESCRIPTION OF THE DRAWINGS

FIG. 1 is a schematic view of a conventional silicon photodetector array;

FIG. 2 is an equivalent circuit of the silicon photodetection module in the example of the present invention;

FIG. 3 is a schematic view of the silicon photodetection module in the example of the present invention;

FIG. 4 is a current-voltage curve of the parasitical vertical bipolar junction transistor amplification unit in the silicon photodetection module of the example of the present invention;

FIG. 5 is a gain chart of the parasitical vertical bipolar junction transistor amplification unit in the silicon photodetection module of the example of the present invention;

FIG. 6 is a resultant curve of the dark current of the silicon photodetection module in the example of the present invention; and

FIG. 7 is a resultant curve of the responsibility of the silicon photodetection module in the example of the present invention.

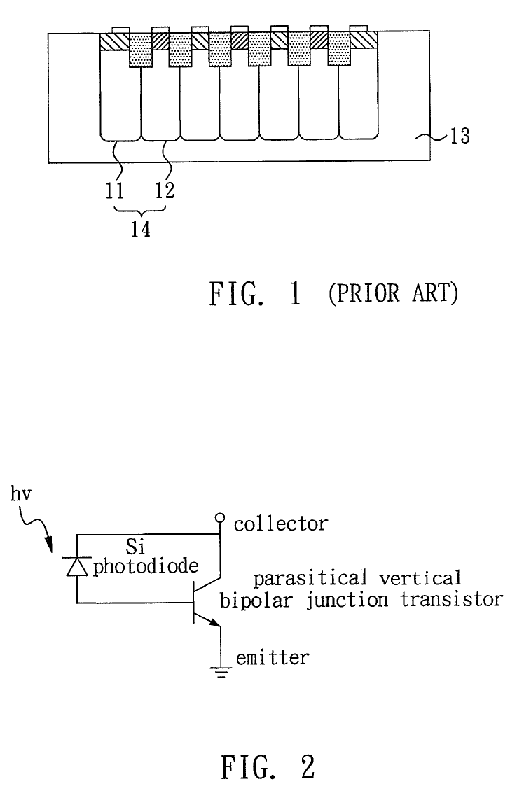

### DETAILED DESCRIPTION OF THE PREFERRED EMBODIMENT

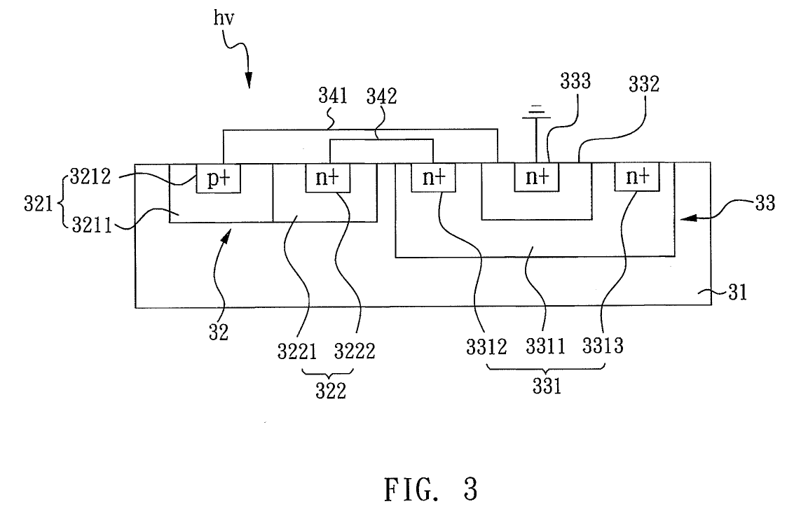

With reference to FIGS. 2 and 3, there is respectively shown an equivalent circuit and a schematic view of the silicon photodetection module in the example of the present invention. As shown in FIG. 3, in an example of the present invention, the silicon photodetection module includes: a silicon substrate 31, a silicon photodiode detection unit 32, and a parasitical vertical bipolar junction transistor amplification unit 33. The silicon photodiode detection unit 32 and the parasitical vertical bipolar junction transistor amplification unit 33 are formed on the silicon substrate 31 by a CMOS process. In addition, the silicon photodiode detection unit 32 includes a positive portion 321 and a negative portion 322, and the parasitical vertical bipolar junction transistor amplification unit 33 includes a collector 331, a base 332, and an emitter 333. Besides, the positive portion 321 of the silicon photodiode detection unit 32 is electrically connected with the base 332 of the parasitical vertical bipolar junction transistor amplification unit 33 by a first conductive part 341. The negative portion 322 of the silicon photodiode detection unit 32 is electrically connected with the collector 331 of the parasitical vertical bipolar junction transistor amplification unit 33 by a second conductive part 342.

When the silicon photodetection module is illuminated, the silicon photodiode detection unit 32 generates a corresponding photocurrent (not shown in the figure). The photocurrent is amplified by the parasitical vertical bipolar junction transistor amplification unit 33 when the photocurrent passes therethrough (i.e. a procedure of current amplification), and then output by a collector 3313 of the parasitical vertical bipolar junction transistor amplification unit 33 to undergo subsequent procedures, for example, voltage amplification by CMOS circuit (not shown in the figure) and noise signal elimination. Furthermore, as shown in FIGS. 2 and 3, in the present example, the emitter 333 of the parasitical vertical bipolar junction transistor amplification unit 33 is connected to ground. Thus, during the operation of the silicon photodetection module, the parasitical vertical bipolar junction transistor amplification unit 33 is operated in a mode of “common emitter”.

Besides, in the silicon photodetection module of the example of the present invention, the silicon substrate 31 is a positive silicon substrate (p-type silicon substrate). The positive portion 321 of the silicon photodiode detection unit 32 includes a positive well (p-well) 3211 and a positive implant region (p-implant) 3212, and the negative portion 322 of the silicon photodiode detection unit 32 includes a negative well (n-well) 3221 and a negative implant region (n-implant) 3222. Specifically, the concentration of the carriers in the positive implant region 3212 is higher than that in the positive well 3211, and the concentration of the carriers in negative implant region 3222 is higher than that in the negative well 3221.

Furthermore, in the silicon photodetection module of the example of the present invention, the collector 331 of the parasitical vertical bipolar junction transistor amplification unit 33 includes a deep negative well (deep n-well) 3311 and a negative implant region 3312. The base 332 of the parasitical vertical bipolar junction transistor amplification unit 33 is a positive well (p-well). The emitter 333 of the parasitical vertical bipolar junction transistor amplification unit 33 is a negative implant region. In addition, the collector 331 of the parasitical vertical bipolar junction transistor amplification unit 33 further includes an output negative implant region 3313 to output current amplified by the parasitical vertical bipolar junction transistor amplification unit 33. The output negative implant region 3313 is electrically connected with a CMOS circuit (not shown in the figure) for the amplified current to undergo subsequent procedures.

In the present example, the aforesaid first conductive part 341 and second conductive part 342 are respective gold wires. As shown in FIG. 3, the first conductive part 341 electrically connects the positive implant region 3212 of the positive portion 321 of the silicon photodiode detection unit 32 and the base 332 of the parasitical vertical bipolar junction transistor amplification unit 33. The second conductive part 342 electrically connects the negative implant region 3222 of the negative portion 322 of the silicon photodiode detection unit 32 and the negative implant region 3312 of the collector 331 of the parasitical vertical bipolar junction transistor amplification unit 33. Furthermore, in the present example, the wavelength of the light detected by the silicon photodetection module of the present invention ranges from 350 nm to 1000 nm, i.e. the light wavelength applied in a short wavelength optical communication system.

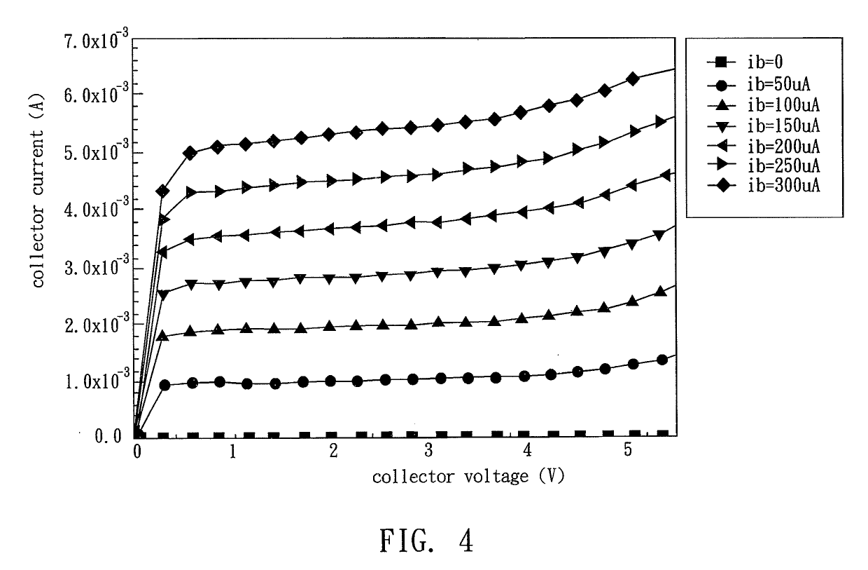

FIG. 4 is a current-voltage curve of the parasitical vertical bipolar junction transistor amplification unit in the silicon photodetection module of the example of the present invention. In FIG. 4, the x-axis shows the voltage of the collector (Vc), and the y-axis shows the current of the collector (Ic). It can be seen from FIG. 4 that the parasitical vertical bipolar junction transistor amplification unit has a relatively high Early voltage.

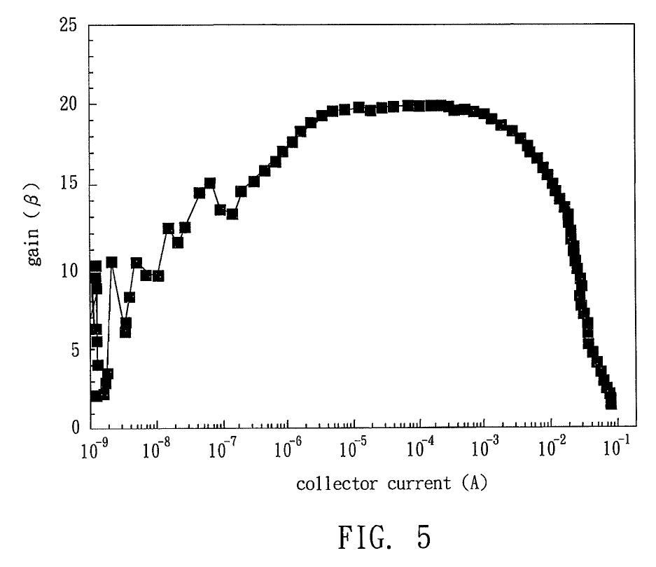

FIG. 5 is a gain chart of the parasitical vertical bipolar junction transistor amplification unit in the silicon photodetection module of the example of the present invention. In FIG. 5, the x-axis shows the current of the collector (Ic), and the y-axis shows gain (β). It can be seen from FIG. 5 that the parasitical vertical bipolar junction transistor amplification unit exhibits considerable gain (β is around 10) under a small collector current (Ic=10⁻⁹ A to 10⁻⁸ A), and thus slight photocurrent can be efficiently amplified. When the collector current ranges from 10⁻⁵ A to 10⁻³ A, the parasitical vertical bipolar junction transistor amplification unit shows the largest gain (β is around 20).

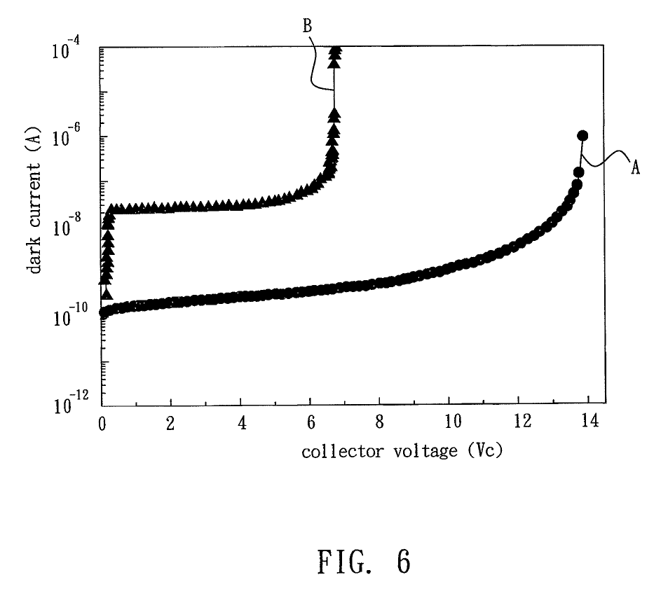

FIG. 6 is a resultant curve of the dark current of the silicon photodetection module in the example of the present invention. In FIG. 6, the x-axis is the voltage of the collector (Vc), and the y-axis is the dark current. The curve A is the measurement result of a conventional silicon photodetection module (i.e. only including a silicon photodiode detection unit), and the curve B is the measurement result of the silicon photodetection module of the present invention (i.e. including both of the silicon photodiode detection unit and the parasitical vertical bipolar junction transistor amplification unit. It can be seen from FIG. 6 that the silicon photodetection module of the present invention still exhibits dark current in an acceptable range (remarkably lower than 10⁻⁶ A) even though the silicon photodetection module of the present invention is constituted by a silicon photodiode detection unit and a parasitical vertical bipolar junction transistor amplification unit.

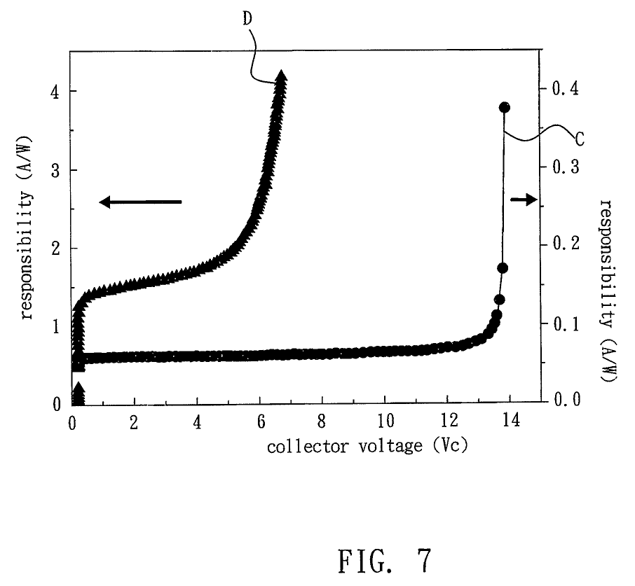

FIG. 7 is a resultant curve of the responsibility of the silicon photodetection module in the example of the present invention. In FIG. 7, the x-axis is the voltage of the collector (Vc), and the y-axis is the responsibility. The curve C is the measurement result of a conventional silicon photodetection module (i.e. only including a silicon photodiode detection unit), and the curve D is the measurement result of the silicon photodetection module of the present invention (i.e. including both of the silicon photodiode detection unit and the parasitical vertical bipolar junction transistor amplification unit). It can be seen from FIG. 7 that the responsibility of the conventional silicon photodetection module (i.e. only including a silicon photodiode detection unit) is less than 0.1 A/W under any collector voltage (Vc). Only when the collector voltage (Vc) approximately increases to 14 V, the responsibility just increases sharply to 0.4 A/W. However, the responsibility of the silicon photodetection module of the present invention (i.e. including both of the silicon photodiode detection unit and the parasitical vertical bipolar junction transistor amplification unit) rapidly increases to about 1.5 A/W when the collector voltage (Vc) is slightly larger than 0 V, and keeps on increasing. Finally when the collector voltage (Vc) approaches 6 V, the responsibility of the silicon photodetection module sharply rises to 4 A/W.

Accordingly, it can be seen from FIGS. 6 and 7 that the silicon photodetection module of the present invention can keep its dark current approximate to that of the conventional silicon photodetection module, and also shows the responsibility much larger than that of the conventional silicon photodetection module. The responsibility of the silicon photodetection module of the present invention can be up to 10 times or more as large as that of the convention silicon photodetection module.

In conclusion, since the parasitical vertical bipolar junction transistor amplification unit comprised in the silicon photodetection module of the present invention is formed on the silicon substrate by a CMOS process, the CMOS process can simultaneously form the silicon photodiode detection unit and the parasitical vertical bipolar junction transistor amplification unit comprised in the silicon photodetection module of the present invention. Accordingly, the formation of the silicon photodiode detection unit and the parasitical vertical bipolar junction transistor amplification unit can simultaneously be accomplished in the silicon photodetection module of the present invention. Compared with a conventional bipolar phototransistor made by a bipolar complementary metal oxide semiconductor (BiCMOS) process, the silicon photodetection module of the present invention can be made by a relatively simple process and incur low cost. In addition, because there is no need to assemble a plurality of the silicon photodiode detection units into an array, the surface area of the silicon substrate occupied by the silicon photodetection module of the present invention is considerably confined in a small portion, and thus it is advantageous to scale down volume of a photodetector having the silicon photodetection module of the present invention.

Although the present invention has been explained in relation to its preferred embodiment, it is to be understood that many other possible modifications and variations can be made without departing from the scope of the invention as hereinafter claimed.

What is claimed is:

1. A silicon photo-detection module for light detection, comprising:
a silicon substrate;
a silicon photodiode detection unit, comprising a positive portion and a negative portion; and
a parasitical vertical bipolar junction transistor amplification unit, comprising a collector, a base, and an emitter,
wherein the silicon photodiode detection unit and the parasitical vertical bipolar junction transistor amplification unit are formed on the silicon substrate by a complementary metal oxide semiconductor (CMOS) process; the positive portion of the silicon photodiode detection unit is electrically connected with the base of the parasitical vertical bipolar junction transistor amplification unit by a first conductive part; and the negative portion of the silicon photodiode detection unit is electrically connected with the collector of the parasitical vertical bipolar junction transistor amplification unit by a second conductive part.

2. The silicon photo-detection module as claimed in claim 1, wherein the silicon substrate is a positive silicon substrate.

3. The silicon photo-detection module as claimed in claim 1, wherein the emitter of the parasitical vertical bipolar junction transistor amplification unit is connected to ground.

4. The silicon photo-detection module as claimed in claim 1, wherein the positive portion of the silicon photodiode detection unit comprises a positive implant region, and the negative portion of the silicon photodiode detection unit comprises a negative implant region.

5. The silicon photo-detection module as claimed in claim 1, wherein the positive portion of the silicon photodiode detection unit comprises a positive well and a positive implant region, and the negative portion of the silicon photodiode detection unit comprises a negative well and a negative implant region.

6. The silicon photo-detection module as claimed in claim 4, wherein the collector of the parasitical vertical bipolar junction transistor amplification unit comprises a deep negative well and a negative implant region; the base of the parasitical vertical bipolar junction transistor amplification unit is a positive well; and the emitter of the parasitical vertical bipolar junction transistor amplification unit is a negative implant region.

7. The silicon photo-detection module as claimed in claim 6, wherein the first conductive part electrically connects the positive implant region of the positive portion of the silicon photodiode detection unit and the base of the parasitical vertical bipolar junction transistor amplification unit, and the second conductive part electrically connects the negative implant region of the negative portion of the silicon photodiode detection unit and the negative implant region of the collector of the parasitical vertical bipolar junction transistor amplification unit.

8. The silicon photo-detection module as claimed in claim 6, wherein the collector of the parasitical vertical bipolar junction transistor amplification unit further comprises an output negative implant region to output current amplified by the parasitical vertical bipolar junction transistor amplification unit.

9. The silicon photo-detection module as claimed in claim 1, wherein the wavelength of the light ranges from 350 nm to 1000 nm.
